(19) United States
(12) Patent Application Publication
(10) Pub. No.: US 2017/0338166 A1
(43) Pub. Date: Nov. 23, 2017

(54) STRUCTURE, AND ELECTRONIC COMPONENT AND ELECTRONIC DEVICE INCLUDING THE STRUCTURE

(71) Applicant: Panasonic Intellectual Property Management Co., Ltd., Osaka (JP)

(72) Inventors: HONAMI NAWA, Osaka (JP); HIROHISA HINO, Osaka (JP)

(21) Appl. No.: 15/429,930

(22) Filed: Feb. 10, 2017

(30) Foreign Application Priority Data
May 20, 2016 (JP) 2016-101514

(51) Int. Cl. H01L 23/373; C09D 7/12; C09D 5/32; H05K 7/20; C08K 3/34; C08K 9/04; C08K 3/22; C08K 3/28

(52) U.S. Cl. CPC H01L 23/3737; C09D 5/32; C09D 7/1216; C09D 7/1225; C09D 7/1283; H05K 7/20263; C08K 9/04; C08K 2003/2227; C08K 2003/282; C08K 2201/001; C08K 3/34; C08K 2201/005

(57) ABSTRACT

Provided herein is a structure having desirable heat dissipation, particularly a structure having high far-infrared emissivity. An electronic component including such a structure, and an electronic device including the electronic component are also provided. The structure includes a water-based coating material containing inorganic fillers that include a first filler and a second filler. The first filler is an oxide containing at least two elements selected from the group consisting of aluminum, magnesium, and silicon, and has a specific surface area of 7 m²/g to 50 m²/g, and a hydrophobic group on a filler surface. The second filler has a head conductivity of 30 W/m·K or more.

### TECHNICAL FIELD

The technical field relates to a structure capable of dissipating the heat of a heat generator to outside by means of thermal radiation, and to an electronic component and an electronic device including the structure.

### BACKGROUND

The heat density of power devices and semiconductor packages has increased along with miniaturization and increased density of these devices. Electronic components installed in these devices thus require a technique that efficiently dissipates the generated heat of individual electronic components to keep the components below the designed operating temperature.

Fins that take advantage of convection, and heat conduction sheets that take advantage of heat conduction are among the techniques that are commonly used as means to dissipate heat. However, it has become difficult to dissipate heat and keep the temperature below the designed operating temperature of a heat generating device and other such heat generators contained in the product device with the sole use of the traditional approach using heat dissipating means such as above. Heat-dissipating coating materials and heat-dissipating sheets that take advantage of thermal radiation have attracted interest as a means to dissipate heat without requiring an additional space. Particularly, a heat-dissipating coating material using a water-based coating material offers easy handling for coating procedures because it uses water as solvent. Heat-dissipating sheets are also desirable in terms of ease of handling because these sheets only need to be simply attached to a metal casing of the device or to a heat generating device to dissipate heat.

FIG. 6 is a cross sectional view of a heat generator 16 provided with a heat-dissipating material 15 produced by using, for example, the method described in JP-A-7-190675. As illustrated in FIG. 6, the heat-dissipating material 15 is in contact with, the heat generator 16 (for example, an IC chip), and dissipates the heat of the heat generator 16. The heat-dissipating material 15 is a sheet-like material formed by compression molding of a mixture containing a granular cordierite powder 21 as a thermal radiation material of large thermal emissivity, and a copper powder 22 as a heat conductive material of large heat conductivity, using dimethyl silicone 20 as a base material.

### SUMMARY

The heat-dissipating material 15 of the related, art is produced as follows. A sheet material A (17) contains only the granular cordierite powder 21 added to the dimethyl silicone 20. A sheet material B (18) contains both the granular cordierite powder 21 and the copper powder 22 added to the dimethyl silicone 20. A sheet material C (19) contains only the copper powder 22 added to the dimethyl silicone 20. A laminate of these three sheet materials A, B, and C, laminated in this order, is stretched with a compression roller. This forms the heat-dissipating material 15 of a three-layer structure. Apparently, the granular cordierite powder 21 and the copper powder 22 that act to dissipate heat are present only in small amounts at the layer interfaces, and transfer of heat is insufficient at these interfaces. This may lead to insufficient diffusion of heat from the heat generator 16 to the surface of the heat-dissipating material 15, and reduced radiation and dissipation of heat.

It is accordingly an object of the present disclosure to provide a structure having desirable heat dissipation, particularly, a structure having high, far-infrared, emissivity. The disclosure is also intended to provide an electronic component including such a structure, and an electronic device including the electronic component.

A structure according to an aspect of the present disclosure includes a water-based coating material containing inorganic fillers that include a first filler and a second filler,

wherein the first filler is an oxide containing at least two elements selected from the group consisting of a aluminum, magnesium, and silicon, and has a specific surface area of 7 m²/g to 50 m²/g, and a hydrophobic group on a filler surface, and

wherein the second filler has a heat conductivity of 30 W/m·K or more.

It is preferable that the structure of the aspect of the present disclosure has a film-like shape. Preferably, the first filler and the second filler each have a concentration gradient in a thickness direction of the film, and the structure of the aspect of the present disclosure has a graded structure.

It is preferable that the first filler has a particle size of 0.6 μm to 10 μm, and that the second filler has a particle size of 10 μm to 100 μm. Preferably, the structure contains the inorganic fillers in an amount of 66.3 volume % to 85.2 volume % with respect to a total volume of the structure.

According to another aspect of the present disclosure, an electronic component including the structure, and an electronic device including the electronic component are provided.

In the aspect of the disclosure, the structure includes a first filler and a second filler (these will be described later in detail), and has a film-like shape. Particularly, the structure has a graded structure because of the concentration gradients of the first and second fillers in a thickness direction of the film, and can have high heat dissipation characteristics. A heat generating device provided with such a structure can efficiently radiate the generated heat into air. This makes it possible to reduce the heat energy of the heat generating device, and inhibit temperature increase in the heat generating device. With the foregoing structure, temperature increase can be effectively inhibited without having the need to install fins or heatsinks. The structure of the aspect of the present disclosure can be configured from a one-component coating material, and can be produced by using a very simply method.

### BRIEF DESCRIPTION OF THE DRAWINGS

FIG. 1 is a cross sectional view schematically representing a structure of an embodiment of the present disclosure, and an electronic component including the structure.

FIG. 2 is a cross sectional view schematically representing a heat dissipation evaluation device used to evaluate the structure of the embodiment of the present disclosure.

FIG. 3 is a cross sectional view schematically representing a heat dissipation evaluation jig used in Examples and Comparative Examples of the present disclosure.

FIG. 4 is a cross sectional view schematically representing a heat dissipation evaluation jig used in Comparative Example 1.

FIG. 5 is a schematic diagram representing an electronic device of as embodiment of the present disclosure.

FIG. 6 is a cross sectional view of an electronic component of related art.

### DESCRIPTION OF EMBODIMENTS

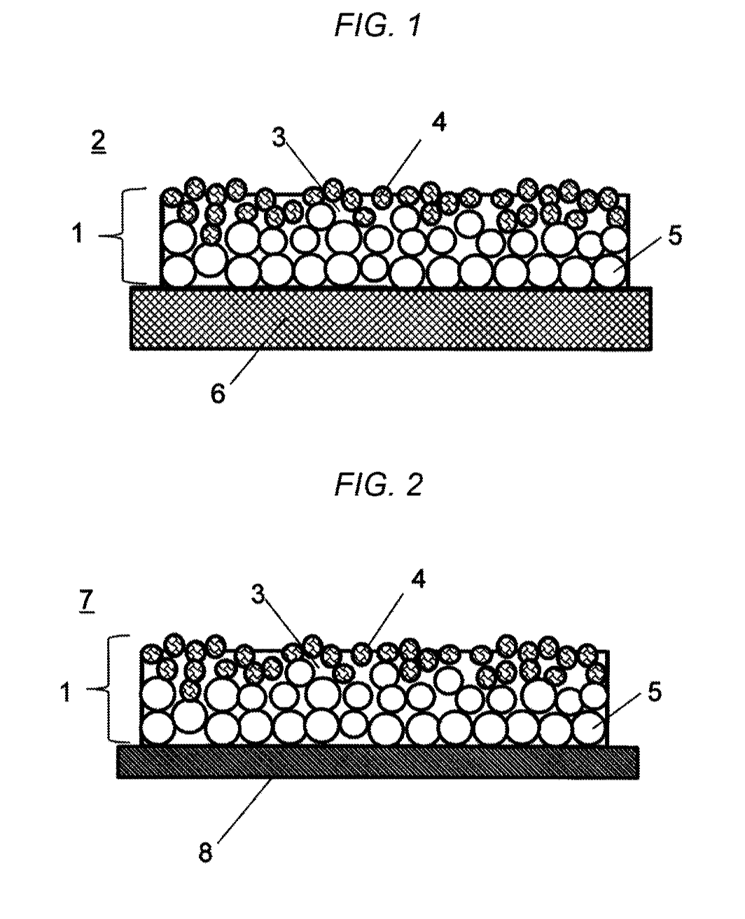

An embodiment of the present disclosure is described below in detail with reference to the accompanying drawings. The following first describes a structure 1 and an electronic component 2 of the embodiment of the present disclosure in detail, with reference to FIG. 1.

### Embodiment

### Structure

FIG. 1 shows a cross sectional view of the structure 1 and the electronic component 2. The structure 1 is configured from a water-based coating material containing inorganic fillers as a mixture of a first filler and a second filler. The first filler is a filler having desirable thermal radiation, and if is an oxide containing at least two elements selected from the group consisting of aluminum, magnesium, and silicon. The first filler has a specific surface area of 7 m²/g to 50 m²/g, and a hydrophobic group on the filler surface, as will be described later in detail. The second filler is a filler having desirable heat conduction, and has a heat conductivity of 30 W/m·K or more. Preferably, the structure 1 has a film-like shape. It is preferable that the first filler and the second filler each have a concentration gradient in a thickness direction of the film, and that the structure 1 has a graded structure.

Preferably, the electronic component 2 of the embodiment of the present disclosure includes the structure 1, and a heat generating device 6.

Preferably, the graded structure is one in which the concentration of first fillers 4 having desirable thermal radiation continuously becomes smaller toward the heat generating device 6, and the concentration of second fillers 5 having desirable heat conduction continuously becomes larger toward the heat generating device 6, for example, as shown in FIG. 1. In this case, it is preferable to design the fillers so that the first fillers 4 are more likely to float than the water-based coating material 3, and that the second fillers 5 are less likely to float than the water-based coating material 3. The water-based coating material 3, the first fillers 4, and the second fillers 5 will be described later in greater detail.

### Water-Based Coating Material 3

The water-based coating material 3 usable in the embodiment of the present disclosure is not particularly limited, as long as the solvent is primarily water, and the material can mix with the first fillers 4 and the second fillers 5 described later. The water-based coating material 3 contains a resin material (a component or a composition) that can form a coating upon curing, and, preferably, a resin that can provide adhesion for metal. Examples of the coating resin formed by the water-based coating material 3 include an epoxy-based resin, a polysiloxane-based resin, and a urethane-based resin. The coating formed by the water-based coating material 3 may contain one or more of these resins.

### Contents of Water-Based Coating Material 3 and Inorganic Fillers

The content of the water-based coating material 3 in the structure 1 after curing is, for example, 14.8 volume % to 33.7 volume %, preferably 16.1 volume % to 30.4 volume % with respect to the total volume of the structure 1, as will be described in detail in the Examples below. Here, the content of the inorganic fillers is, for example, 66.3 volume % to 85.2 volume %, preferably 69.6 volume % to 83.9 volume % with respect to the total volume of the structure 1.

For the total volume, 100 volume %, of the water-based coating material 3 after curing and the inorganic fillers in the structure 1, the inorganic fillers exceed 85.2 volume % when the water-based coating material 3 is below 14.8 volume %. This reduces the area of contact between the water-based coating material 3 and the heat generating device 6, and the adhesion of the structure 1 for the heat generating device 6 may suffer. On the other hand, when the water-based, coating material 3 is above 33.7 volume %, the inorganic fillers will be less than 66.3 volume %. In this case, the fillers will be present without contacting one another, and the heat transfer coefficient becomes smaller in the coating. This may lead to inefficient thermal radiation at the surface of the structure 1.

### Density of Water-Based Coating Material 3

The water-based coating material 3 has a density of, for example, 1.0 g/ml to 1.1 g/ml, preferably 1.0 g/ml to 1.04 g/ml. In order to form a graded structure in the structure it is preferable that the density of the water-based coating material be higher than the density of the first fillers 4, and lower than the density of the second fillers 5, as will be described later in detail.

### First Fillers 4

The first fillers 4 are oxide particles containing at least two elements selected from the group consisting of aluminum, magnesium, and silicon, and having a specific surface area of 7 m²/g to 50 m²/g, and a hydrophobic group on the filler surface, as will be described in detail in the Examples below. Preferably, the first fillers are particles with a particle size of 0.6 μm to 10 μm. Preferably, the first fillers have a far-infrared emissivity of 0.8 or more. The first fillers 4 are described below in greater detail.

### Far-Infrared Emissivity of First Fillers 4

The far-infrared emissivity takes a value of 0 to 1 relative to the ideal emissivity, 1, of what is believed to be the most ideal blackbody.

The far-infrared emissivity is influenced not only by the first fillers 4 that may be present near the surface of the structure 1, but possibly by the water-based coating material 3. Typically, resins have a far-infrared emissivity of 0.6 to 0.8. It is accordingly preferable that the first fillers 4 have a larger far-infrared emissivity than the water-based coating material 3, preferably 0.8 or more, more preferably 0.9 of more. When the far-infrared emissivity of the first fillers 4 is less than 0.8, the far-infrared emissivity of the water-based coating material 3 may become a factor, and lower the far-infrared emissivity of the structure 1 below 0.9. This may result in inefficient thermal radiation.

### Type of First Fillers 4

In order to make the far-infrared emissivity of the structure 1 preferably 0.9 or more, more preferably 0.95 or more, the first fillers 4 used in the present disclosure are basically oxides containing at least two elements selected from the group consisting of aluminum, magnesium, and silicon. By containing at least two components selected from aluminum, magnesium, and silicon, the first fillers 4 can have overlapping peaks of far-infrared emissivity due to these components. This can make the mean value of far-infrared emissivities 0.9 or more in a 5 μm to 20 μm wavelength range that contributes to heat transfer in an electronic component.

Preferably, the first fillers 4 are magnesium, silicates such as talc and cordierite, magnesium-aluminum carbonates such as hydrotalcite, and aluminosilicates such as zeolite and bentonite.

### Density of First Fillers 4

The first fillers 4 have a density of, for example, 0.09 g/ml to 0.30 g/ml, preferably 0.25 g/ml to 0.30 g/ml. As used herein, “density” of the first fillers 4 means density including the volume of pores inside the material of the first fillers 4, specifically bulk density.

In order for the structure 1 to have a graded structure, it is preferable that the first fillers 4 have a smaller density than the water-based coating material 3. In this way, the first fillers 4 become more likely to be present at the surface of the structure 1 (FIG. 1), and enable heat to dissipate from, the surface of the structure 1 by thermal radiation.

### Particle Size of First Fillers 4

The first fillers 4 have a particle size of, for example, 0.6 μm to 10 μm, preferably 8 μm to 10 μm. When the particle size of the first fillers 4 is smaller than 0.6 μm, the first filler 4 will be present between particles of the second fillers 5, and fail to form, a graded structure in the structure 1. This may result in inefficient thermal radiation. On the other hand, when the particle size of the first fillers 4 is larger than 10 μm, the first fillers 4 and the second fillers 5 will have a smaller particle size difference, and the second fillers 3 will be present also at the surface of the structure 1. This makes it difficult to form a graded structure in the structure 1, and may result in inefficient thermal radiation.

### Specific Surface Area of First Fillers 4

The first fillers 4 have a specific surface area of 7 m²/g to 50 m²/g, preferably 7 m²/g to 10 m²/g. The specific surface area increases, and the density decreases when the fillers have larger numbers of pores for a given particle size. This makes it easier for the first filler 4 to be present at the surface of the structure 1 when forming the structure 1.

When the specific surface area of the first fillers 4 is smaller than 7 m²/g, the density difference between the first fillers 4 and the second fillers 5 will be smaller, and smaller numbers of first fillers 4 will be present at the surface of the structure 1 when forming the structure 1. This may result in inefficient thermal radiation.

When the specific surface area of the first, fillers 4 is larger than 50 m²/g, the density decreases, and the first fillers 4 disperse throughout the water-based coating material 3 when kneading the material. This make it difficult to form, a graded structure in the structure 1, and may result in inefficient thermal radiation.

### Surface Treatment of First Fillers 4

The first fillers 4 have a hydrophobic group (a functional group with hydrophobicity) on their surfaces. With the hydrophobic surfaces imparted by the hydrophobic group, the first fillers 4 can be present at the surface of the structure 1 in large numbers. The first fillers 4 contain oxides that contain at least two elements selected from the group consisting of aluminum, magnesium, and silicon, as described above, and are inherently hydrophilic with the surface hydroxyl group. The surfaces of the first fillers 4 can be rendered hydrophobic by forming a hydrophobic group on the surfaces of the first fillers 4 by a surface treatment that treats the surface hydroxyl group with a surface treatment agent.

Examples of the surface treatment agent include fatty acid ester-type non-ionic surfactants, and silane coupling agents. The hydrophobic group that may be formed, on the surfaces of the first fillers 4 may be, for example, a group containing a long-chain fatty acid group of 10 to 30 carbon atoms derived from fatty acids such as stearic acid, or a group containing two functional groups, specifically, an organic functional group of 2 to 10 carbon atoms, such as vinyl, glycidoxypropyl, and methacryloxypropyl, and an alkoxy group of 1 to 6 carbon atoms, such, as methoxy, and ethoxy.

### Second Fillers 5

The second fillers 5 have a heat conductivity or 30 W/m·k or more, as will be described in detail in the Examples below. The second fillers 5 have a particle size of, for example, 10 μm to 100 μm, preferably 10 μm to 2 μm.

### Particle Size of Second Fillers 5

When the particle size of the second fillers 5 is smaller than 10 μm, the particle size difference between the first fillers 4 and the second fillers 5 will be smaller, and the second fillers 5 will be present also at the surface of the structure 1. This makes it difficult to form a graded structure, and may result in inefficient thermal radiation. On the other hand, when the particle size of the second fillers 5 is larger than 100 μm, there will be a risk of creating gaps between particles of the second fillers 5, and the heat conduction in the coating of the structure 1 may become insufficient.

### Density of Second Fillers 5

In order for the structure 1 to have a graded structure, it is preferable that the second fillers 5 have a larger density than the water-based coating material 3. In this way, the second fillers 5 become more likely to be present at the bottom surface of the structure 1 closer to the heat generating device 6 (FIG. 1), and the heat of the heat generating device 6 can efficiently diffuse to the structure 1. The density of the second fillers 5 is, for example, 1.1 g/ml to 3 g/ml, preferably 1.1 g/ml to 2.6 g/ml.

### Heat Conductivity of Second Fillers 5

The second fillers 5 have a heat conductivity of, for example, 30 W/m·K or more, and the upper limit is not particularly limited. When the heat conductivity of the second fillers 5 is less than 30 W/m·K, the generated heat of the heat generating device 6 may fail to efficiently diffuse in the structure 1.

### Type of Second Fillers 5

The material of the second fillers 5 is not particularly limited, as long as it has a heat conductivity of 30 W/m·K or more. Examples of such materials include alumina, aluminum nitride, and silicon carbide.

### Mixture Ratio of First Fillers and Second Fillers

The mixture ratio of the first fillers and the second fillers (first fillers:second fillers) is not particularly limited, and is, for example, 1:1 to 1:2.5, preferably 1:1 to 1:2 by weight. The mixture ratio is 1:0.11 to 1:1, preferably 1:0.11 to 1:0.75 by volume. Formation of a graded structure becomes easier with these mixture ratios.

### Electronic Component

In the embodiment of the present disclosure, the electronic component 2 includes at least the structure 1, and a heat generating device 6 for a heat generator), and these may be in contact with each other. In the structure 1 of the electronic component 2, it is preferable that the second fillers 5 are in contact with the heat generating device 6. The heat generating device 6 is not particularly limited, as long as it generates heat, and may be, for example, a power module, or an LED device.

### Electronic Device

In the embodiment of the present disclosure, the electronic device is not particularly limited, as long as it includes at least the electronic component 2. Examples of the electronic device include smartphones, tablet terminals, illumination equipment, and control units for industrial devices.

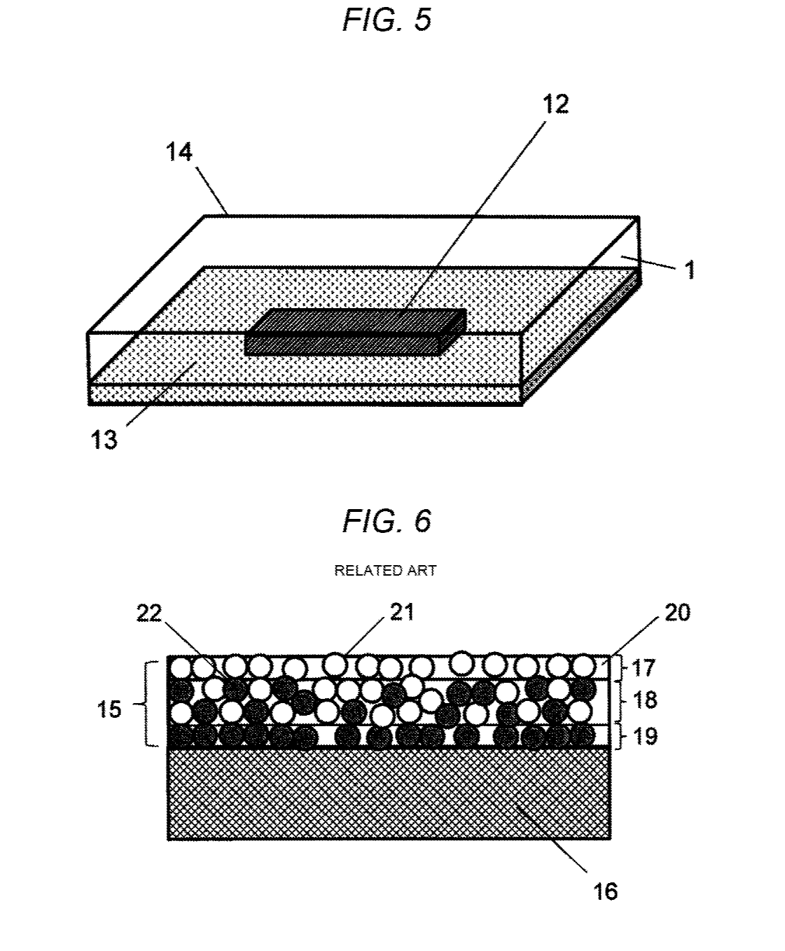

As an example, FIG. 5 illustrates an electronic device of the embodiment of the present disclosure configured from a structure 1, a heat generator 12, a substrate 13, and a tablet casing 14. The present disclosure is applicable to dissipate heat in electronic devices that are too small, light, and thin to accommodate fans or heatsinks, as in this example.

The following Examples describe the present disclosure in greater detail. It is to be noted that the present disclosure is in no way limited by the following Examples.

### EXAMPLES 1 TO 8, AND COMPARATIVE EXAMPLES 1 TO 7

Tables 1 to 4 show the contents and other conditions of the water-based coating materials and the inorganic fillers used to produce the structures of Examples 1 to 8 and Comparative Examples 1 to 7, Tables 1 to 4 also show the heat dissipation characteristics of the structures obtained in Examples and Comparative Examples. The heat dissipation characteristics will be described later in detail.

In Tables 1 to 4, the filler contents (weight %, and volume %) are based on the structure 1 after the coating of the water-based coating material 3 (structure 1 after drying and curing), and do not represent the amounts mixed with the water-based coating material 3 to form the coating.

A heat dissipation evaluation device 7 including the structure 1 shown in FIG. 2 was fabricated under the conditions shown in Tables 1 to 4 to evaluate the heat dissipation characteristics of the structure 1. The heat dissipation evaluation device 7 is configured from the structure 1 and a metal substrate 8.

### Structure 1

The production, of the structure 1 is described below, taking Example 1 as an example.

A talc (MICRO ACE K-1, Nippon Talc Co., Ltd.) having a particle size of 8 μm, a specific surface area of 7.0 m²/g, and a density of 0.25 g/ml was used as first fillers 4. An alumina (A9-C1, Admatechs) having a particle size of 14 μm, a specific surface area of 1.0 m²/g, and a density of 1.10 g/ml was used as second fillers 5. An aqueous siloxane-acrylic resin (Ceranate WSA-1070, DIG) having a density of 1.04 g/ml was used as water-based coating material 3.

A surface improver (Rheodol SP-O30V, Kao Corporation) was applied to the surfaces of the first fillers 4 in an amount of 0.5 weight % with respect to the fillers, and the first fillers 4 were kneaded in a mortar.

Thereafter, 29.8 weight parts of the water-based coating material 3, 17.6 weight parts of the first fillers 4 (after treatment with 0.1 weight parts of the surface improver; first fillers 4: 17.5 weight parts, the surface improver; 0.1 weight parts) and 17.5 weight parts of the second fillers 5 were mixed to produce a mixture that had a filler content of 70 weight % after coating formation. Here, 14.9 weight parts, or 50 weight %, of the water-based, coating material 3 is the solvent water. The solvent is evaporated in a coating curing step.

The mixture was applied to the metal substrate 8 (60 mm×60 mm×1 mm) In a thickness of 60 μm using a metal mask and a squeegee, and cured at 80° C. for 20 min to produce the structure 1. The structure 1 coated has a thickness of 50 μm after evaporation of the solvent water in the water-based coating material 3. This completed the heat dissipation evaluation device 7.

The first fillers 4 and the second fillers 5 had gradually changing concentrations along the thickness direction of the structure 1, and the structure 1 had a graded structure containing larger numbers of first fillers 4 on the surface of the structure 1, with some of the first fillers 4 projecting out of the water-based coating material 3. The second fillers 5 were more abundant near the metal substrate 8, and some of the second fillers 5 were in contact with the surface of the metal substrate 8.

### Heat Dissipation Evaluation Jig

For the evaluation of the heat dissipation characteristics of the structure 1, the heat dissipation evaluation jig shown in FIG. 3 was produced using the heat dissipation evaluation device 7 produced above. FIG. 3 is a cross sectional view of the heat dissipation evaluation jig. The heat dissipation evaluation jig includes the heat dissipation evaluation device 7, a heater 9, and a heat radiation absorber 10. The heat dissipation evaluation device 7 was produced by forming the structure 1 on the metal substrate 8 in the manner described above.

An aluminum substrate was prepared as the metal substrate 8. The heater 9 (60 mm×60 mm×10 mm) with a built-in thermocouple was mounted on the back surface of the heat dissipation evaluation device 7 by being attached with a heat dissipating silicone grease.

The heat radiation absorber 10 includes the heat dissipation evaluation, device 7, and a water-cooled, heatsink 11. The heat radiation absorber 10 was produced by attaching the water-cooled heatsink 11 (60 mm×60 mm×10 mm) to the back surface of the heat dissipation evaluation, device 7 (the surface opposite the structure 1) with a heat dissipating silicone grease. A chiller was attached to the water-cooled heatsink it, and the temperature of the heat radiation absorber 10 was maintained constant at 25° C. by circulating 25° C. water.

### EXAMPLES 1 TO 8

The heat dissipation evaluation device 7 with the structure 1, and the heat dissipation evaluation jig were produced by following the procedures described above, using the conditions shown in Tables 1 to 4.

### COMPARATIVE EXAMPLE 1

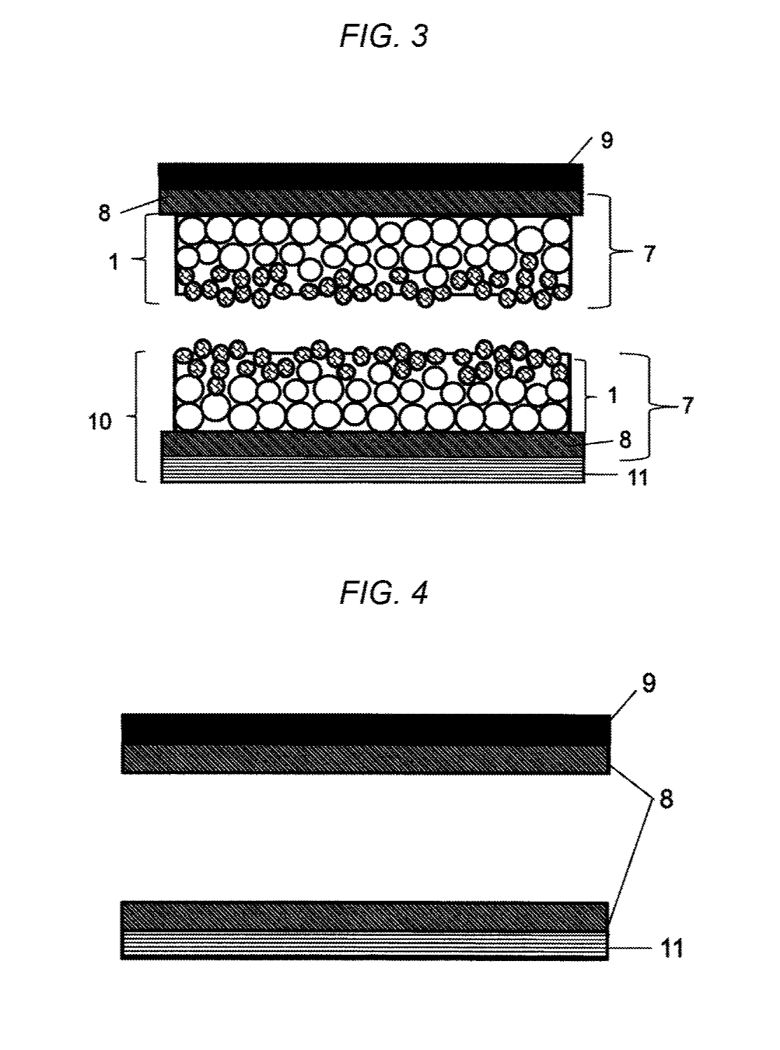

In Comparative Example 1, the heat dissipation evaluation, jig shown in the cross sectional view of FIG. 4 was produced without the structure 1. As such, the heat dissipation evaluation jig shown in FIG. 4 differs from the heat dissipation evaluation jig of FIG. 3 in that the structure 1 is absent. The heat dissipation evaluation jig shown in FIG. 4 includes the metal substrate 8, the heater 9, and the water-cooled heat sink 11. These are the same as those used in FIG. 3.

### COMPARATIVE EXAMPLE 2

In Comparative Example 2, the first fillers 4 were not subjected to the surface treatment with a surface improver. The water-based coating material 3, the first fillers 4, and the second fillers 5 were mixed under the conditions shown in Table 1, and the heat dissipation evaluation device 7, and the heat dissipation evaluation jig shown in FIG. 3 were produced by following the procedures described above.

### COMPARATIVE EXAMPLES 3 to 7

In Comparative Examples 3 to 7, the structure 1 was produced in the same manner as in Example 1 using the foregoing procedures under the conditions shown in Tables 2 to 4, and the heat dissipation evaluation jig shown in FIG. 3 was produced.

The heat dissipation evaluation devices including the structures produced in Examples and Comparative Examples were measured for far-infrared emissivity, and temperature change for inhibition of temperature increase to evaluate the heat dissipation characteristics, specifically, thermal radiation, and inhibition of temperature increase. These were evaluated as follows.

### Measurement of Far-Infrared Emissivity

Far-infrared emissivity was measured for each sample of the heat dissipation evaluation devices 7 of Examples and Comparative Examples excluding Comparative Example 1, using a quick emissivity measurement device (Model: TSS-5X, Japan Sensor Corporation). Here, the far-infrared emissivity is a mean value of spectral far-infrared emissivities in a 2 to 22 μm wavelength range.

Samples were determined as Good when the far-infrared emissivity was 0.9 or more, and Poor when the far-infrared emissivity did not satisfy this condition. The results are presented in Tables 1 to 4.

### Measurement of Temperature Change for Inhibition of Temperature Increase

The heat dissipation evaluation jig including the heat dissipation evaluation device 7 of Examples and Comparative Examples was installed in a 25° C. thermostat bath, and current was passed through the heater 9 under windless conditions.

The heat dissipation evaluation jigs of Examples 1 to 8 and Comparative Examples 2 to 7 including the structure 1 were measured under increasing voltages to determine the temperature difference ΔT of the heater 9 from the heater temperature (127° C.) measured for the heat dissipation evaluation jig of Comparative Example 1 that did not include the structure 1, using the following formula 1.

ΔT=[(127° C.)−(temperature of heater 9)] Formula 1

For example, the temperature difference (ΔT) was 7° C. in Example 1 in which the structure 1 was formed on the metal substrate 8 (Table 1).

The percentage inhibition of temperature increase can be represented by the following formula 2.

Percentage inhibition of temperature increase (%)=ΔT/127×100 Formula 2

The percentage inhibition of temperature increase is about 5% for many of heat-dissipating coating materials using water-based coating materials. Accordingly, samples were determined as Poor when the percentage inhibition of temperature increase was less than 3%, Moderate when the percentage inhibition of temperature increase was 3% or more and less than 5%, and Good when the percentage inhibition of temperature increase was 5% or more.

It is desirable to have larger values of percentage inhibition of temperature increase. However, samples were determined as acceptable when the percentage inhibition of temperature increase was 3% or higher. A percentage inhibition of temperature increase of less than 3% is not effective when costs such as that for applying paste are considered, though it may be sufficient in certain applications.

### Overall Determination of Heat Dissipation Characteristics

The overall determination of heat dissipation characteristics used the following criteria. Specifically, samples were determined overall as Excellent when the result of the far-infrared emissivity measurement, and the result of the measurement of temperature change for inhibition of temperature increase were both Good. Samples were determined overall as Poor when the result of either of these measurement results was Poor. The overall determination was Good for other samples.

TABLE 1

| Main components | Details | Content | Ex. 1 | Com. Ex. 1 | Com. Ex. 2 |
|---|---|---|---|---|---|
| Water-based | Aqueous | Ceranate WSA-1070 (excl. water), | 14.9 | No | 14.9 |
| coating | siloxane-acrylic | density 1.04 g/ml | | application | |
| material | resin | | | of | |
| First filler | Talc | MICRO ACE K-1, particle size 8.0 μm, | 17.5 | composition | |
| | (Mg [symbol] Si [symbol] O [symbol] (OH)₂) | density 6.25 g/ml, specific surface | | | |
| | | area 7.0 m²/g | | | |
| Second filler | Alumina (Al₂O₃₎ | A [symbol] -Cl, particle size 14.0 μm, | 17.5 | | 17.5 |
| | | density 1.1 g/ml, specific surface | | | |
| | | area 1.0 m²/g | | | |
| Additive | Surface improver | Rheodol SPO-30V | 0.1 | | — |
| Total (weight parts) | | | 50.0 | | 49.9 |
| Filler content (weight %) | | | 70.0 | | 70.1 |
| Filler content (volume %) | | | 83.9 | | 83.9 |
| Heat | Heat radiation | Far-infrared emissivity (—) | 0.95 | 0.09 | 0.89 |
| dissipation | | Determination (—) | Good | Poor | Poor |
| characteristics | Inhibition of | Measured value (° C.) | 120 | 127 | 123 |
| | temperature | Temperature difference ΔT (° C.) | 7 | — | 4 |
| | increase | Percentage inhibition of | 5.5 | — | 3.3 |
| | | temperature increase (%): Heat | | | |
| | | dissipation | | | |
| | | Determination (—) | Good | — | Moderate |
| | Overall | Determination (—) | Excellent | — | Poor |
| | determination | | | | |

[symbol]

indicates data missing or illegible when filed

Samples were evaluated for the presence or absence of a surface treatment of the first fillers 4 (the presence or absence of a hydrophobic group). The results are presented in Table 1.

### Table 1: Discussions

### Surface Treatment of First Fillers 4

By comparing Example 1 and Comparative Example 2, the hydrophobic surface treatment of the first fillers 4 in Example 1 added a hydrophobic group to the surface, and the first fillers 4 were more likely to float than the water-based coating material 3 in the coating of the structure 1. Accordingly, the structure 1 had a structure with large numbers of first fillers 4 on its surface.

As demonstrated above, a surface treatment of the first fillers 4 with, a surface treatment agent was indeed desirable.

### Density of First Fillers 4 and Second Fillers 5

In Example 1, the first fillers 4 and the second fillers 5 had densities of 0.25 g/ml and 1.10 g/ml, respectively, whereas the density of the water-based coating material 3 was 1.04 g/ml. Accordingly, the structure 1 had a graded structure in which the first fillers 4 were more likely to float than, the water-based coating material 3, and the second fillers 5 were less likely to float than the water-based coating material 3.

As demonstrated above, it was indeed desirable to make the density of the first fillers 4 smaller, and the density of the second fillers 5 larger than the density of the water-based coating material 3 in order to form a graded structure in the structure 1.

TABLE 2

| | | | | | | | Com. | Com. |
|---|---|---|---|---|---|---|---|---|
| Main components | Details | | Ex. 2 | Ex. 3 | Ex. 4 | Ex. 5 | Ex. 3 | Ex. 4 |
| Water-based | Aqueous siloxane-acrylic resin | | 14.9 | | | | | |
| coating | | | | | | | | |
| material | | | | | | | | |
| First filler | Talc (Mg₃Si₄O₁₀(OH)₂) | | 7.0 | | | | | |
| | | Average particle size | 8.0 | 0.6 | 10.0 | 1.5 | 15.0 | 0.1 |
| | | (μm) | | | | | | |
| | | Density (g/ml) | 0.25 | 0.09 | 0.30 | 0.12 | 0.35 | 0.05 |
| | | Specific surface area | 7.0 | 24.0 | 10.0 | 50.0 | 4.0 | 100.0 |
| | | (m²/g) | | | | | | |
| Second filler | Alumina (Al₂O₃) | | 17.5 | | | | | |
| | | Average particle size | 14.0 | | | | | |
| | | (μm) | | | | | | |
| Additive | Surface improver | | 0.035 | | | | | |
| Total (weight parts) | | | 39.4 | | | | | |
| Filler content (weight %) | | | 62.1 | | | | | |
| Filler content (volume %) | | | 69.6 | 85.2 | 66.3 | 81.5 | 63.4 | 91.0 |
| Heat | Heat | Far-infrared | 0.95 | 0.90 | 0.92 | 0.91 | 0.83 | 0.85 |
| dissipation | radiation | emissivity (—) | | | | | | |
| characteristics | | Determination (—) | Good | Good | Good | Good | Poor | Poor |
| | Inhibition of | Measured value (° C.) | 120 | 123 | 119 | 123 | 124 | 125 |
| | temperature | Temperature | 7 | 4 | 3 | 4 | 3 | 2 |
| | increase | difference ΔT (° C.) | | | | | | |
| | | Percentage inhibition | 5.5 | 3.1 | 6.3 | 3.1 | 2.4 | 1.6 |
| | | of temperature | | | | | | |
| | | increase (%): Heat | | | | | | |
| | | dissipation | | | | | | |
| | | Determination (—) | Good | Moderate | Good | Moderate | Poor | Poor |
| | Overall | Determination (—) | Excellent | Good | Excellent | Good | Poor | Poor |
| | determination | | | | | | | |

In Table 2, the second fillers 5 are alumina having a particle size of 14 μm, as in Example 1. The heat dissipation characteristics were evaluated by using talcs of different particle sizes, different densities, and different specific surface areas as first fillers 4. In Examples 2 to 5 and Comparative Examples 3 to 4, the first fillers 4 were subjected to a surface treatment to render the filler surface hydrophobic.

### Table 2: Discussions

Particle size, Density, and Specific Surface Area of First Fillers 4

By comparing Examples 2 to 5 with Comparative Example 3, the first filler talc used in Comparative Example 3 had a particle size of 15 μm, a specific surface area of 4.0 m²/g, and a density of 0.35 g/ml. Because of the large first filler density of Comparative Example 3, the second fillers were also present at the surface of the structure 1, and the structure 1 failed to have a graded structure. The thermal radiation was poor accordingly.

By comparing Examples 2 to 5 with Comparative Example 4, the first filler talc used in Comparative Example 4 had a particle size of 0.1 μm, a specific surface area of 100 m²/g, and a density of 0.05 g/ml. In Comparative Example 4, particles of the first fillers 4 were also present between particles of the second fillers 5, and the structure 1 failed to have a graded structure. The thermal radiation was poor accordingly.

It was found from the results of Examples 2 to 5 that the preferred particle size of the first fillers 4 was 0.6 μm to 10 μm, and the preferred specific surface area of the first fillers 4 was 7 m²/g to 50 m²/g.

### Content of Inorganic Fillers

By comparing Examples 2 to 5 with Comparative Example 3, the inorganic filler content was 63.4 volume % in Comparative Example 3, and the fillers were not able to contact one another. Accordingly, the heat transfer coefficient in the coating was smaller, and the thermal radiation at the surface of the structure 1 was poor.

By comparing Examples 2 to 5 with Comparative Example 4,the inorganic filler content was 91.0 volume %, and the content of the water-based coating material was small in Comparative Example 4. This is detrimental to the adhesion for an object to which the structure 1 is applied, and the ease of handling suffers.

It was found from, the results of Examples 2 to 5 that the preferred filler content was 66.3 volume % to 85.2 volume %.

TABLE 2

| Main components | Details | | Ex. 1 | Ex. 6 | Ex. 7 | Com. Ex. 5 |
|---|---|---|---|---|---|---|
| Water-based | Aqueous siloxane-acrylic resin | | 14.9 | 14.9 | 14.9 | 14.9 |
| coating | | | | | | |
| material | | | | | | |
| First filler | Talc (Mg₃Si₄O₁₀(OH)₂) | | 17.5 | | | |
| Second filler | Alumina (Al₂O₃) | | 17.5 | | | |
| | Aluminum nitride (AlN) | | | 17.5 | | |
| | Silicon carbide (SiC) | | | | 17.5 | |
| | Zinc oxide (ZnO) | | | | | 17.5 |
| | Heat conductivity (W/m · K) | | 30.0 | 150.0 | 200.0 | 5.0 |
| | Average particle size (μm) | | 14.0 | 10.0 | 10.0 | 10.0 |
| Additive | Surface improver | | 0.1 | | | |
| Total (weight parts) | | | 50.0 | 50.0 | 50.0 | 50.0 |
| Filler content (weight %) | | | 70.0 | 70.0 | 70.0 | 70.0 |
| Filler content (volume %) | | | 83.9 | 83.9 | 84.0 | 83.5 |
| Heat | Heat radiation | Far-infrared emissivity (—) | 0.95 | 0.90 | 0.93 | 0.70 |
| dissipation | | Determination (—) | Good | Good | Good | Poor |
| characteristics | Inhibition of | Measured value (° C.) | 120 | 117 | 115 | 123 |
| | temperature | Temperature difference ΔT (° C.) | 7 | 10 | 12 | 4 |
| | increase | Percentage inhibition of | 5.5 | 7.9 | 9.4 | 3.1 |
| | | temperature increase (%): Heat | | | | |
| | | dissipation | | | | |
| | | Determination (—) | Good | Good | Good | Moderate |
| | Overall | Determination (—) | Excellent | Excellent | Excellent | Poor |
| | determination | | | | | |

In Table 3, the first fillers 4 are a talc having a particle size of 8 μm, and a specific surface area of 7 m²/g as in Example 1. The heat dissipation characteristics were evaluated by using fillers of different heat conductivities as second fillers 5.

### Table 3: Discussions

Heat conductivity of Second Fillers 5

By comparing Examples 1, 6, and 7 with Comparative Example 5, zinc oxide (ZnO) having a heat conductivity of 5 W/m·K was used as second fillers 5 in Comparative Example 5. In Comparative Example 5, the generated heat from the metal substrate 8 did not efficiently diffuse in the coating of the structure 1, and the thermal radiation was poor.

It was found from the results of Examples 1, 6, and 7 that the preferred heat conductivity of the second fillers 5 was 30 W/m·K or more.

TABLE 4

| Main components | Details | | Ex. 1 | Ex. 8 | Com. Ex. 6 | Com. Ex. 7 |
|---|---|---|---|---|---|---|
| Water-based | Aqueous siloxane-acrylic resin | | 14.9 | 14.9 | 14.9 | 14.9 |
| coating material | | | | | | |
| First filler | Talc (Mg₃Si₄O₁₀(OH)₂) | | 17.5 | | | |
| Second filler | Alumina (Al₂O₃) | | 17.5 | | | |
| | Average particle size (μm) | | 14.0 | 100.0 | 5.0 | 300.0 |
| Additive | Surface improver | | 0.1 | | | |
| Total (weight parts) | | | 50.0 | 50.0 | 50.0 | 50.0 |
| Filler content (weight %) | | | 70.0 | 70.0 | 70.0 | 70.0 |
| Filler content (volume %) | | | 83.9 | 83.9 | 83.9 | 83.9 |
| Heat dissipation | Heat radiation | Far-infrared emissivity | 0.95 | 0.94 | 0.89 | 0.86 |
| characteristics | | (—) | | | | |
| | | Determination (—) | Good | Good | Poor | Poor |
| | Inhibition of | Measured value (° C.) | 120 | 122 | 123 | 125 |
| | temperature | Temperature difference ΔT | 7 | 5 | 4 | 2 |
| | increase | (° C.) | | | | |
| | | Percentage inhibition of | 5.5 | 3.9 | 3.1 | 1.6 |
| | | temperature increase (%): | | | | |
| | | Heat dissipation | | | | |
| | | Determination (—) | Good | Moderate | Moderate | Poor |
| | Overall | Determination (—) | Excellent | Good | Poor | Poor |
| | determination | | | | | |

In Table 4, a talc having a particle size of 8 μm, and a specific surface area of 7 m²/g was used as first fillers 4, as in Example 1. The heat dissipation characteristics were evaluated by using alumina of different particle sizes as second fillers 5.

### Table 4: Discussions

### Particle Size of Second Fillers 5

By comparing Examples 1 and 8 with Comparative Example 6, the second fillers were present also at the surface of the structure 1 in Comparative Example 6 because of the alumina having a particle size of 5 μm used as second fillers 5. Accordingly, it was not possible to form a graded structure, and the thermal radiation was poor.

By comparing Examples 1 and 8 with Comparative Example 7, gaps were created between particles of the second fillers 5 in Comparative Example 7 because of the alumina having a particle size of 300 μm used as second fillers 5. Accordingly, the heat conduction was insufficient in the coating of the structure 1, and inhibition of temperature increase was poor.

In Examples 6 and 7 shown in Table 3, aluminum nitride (AlN) and silicon carbide (SiC) having a particle size of 10 μm were used as second fillers 5, and the samples were desirable in terms of both thermal radiation, and inhibition of temperature increase.

It was found from the results of Examples 1 and 8 shown in Table 4 that particles having a particle size of 10 μm to 100 μm are preferred for use as the second fillers 5.

### OVERALL SUMMARY

As described above, the structure of the present disclosure is configured as a mixture of inorganic fillers in a water-based coating material, and the inorganic fillers include a first filler and a second filler. The first filler is an oxide having at least two elements selected from the group consisting of aluminum, magnesium, and silicon, and has a specific surface area of 7 m²/g to 50 m²/g, and a hydrophobic group on the filler surface. The second filler has a heat conductivity of 30 W/m·K or more. Preferably, the structure of the present disclosure has a graded structure (for example, FIG. 1), and the first filler and the second filler have concentration gradients in thickness direction of the structure.

With such a graded structure, a heat-dissipating structure can be provided that has desirable heat dissipation characteristics, particularly a very high far-infrared emissivity, and excellent ease of handling (Examples 1 to 8).

The structure of the present disclosure can inhibit temperature increase by allowing heat of a heat generator (or a heat generating device) to efficiently radiate to outside.

### INDUSTRIAL APPLICABILITY

The structure of the present disclosure can be used to dissipate heat of a heat generator, and has use particularly in electronic components that include a heat generator, and in electronic devices including such electronic components, for example, such as smartphones, and tablet terminals.

What is claimed is:

1. A structure comprising a water-based coating material containing inorganic fillers that include a first filler and a second filler,
wherein the first filler is an oxide containing at least two elements selected from the group consisting of aluminum, magnesium, and silicon, and has a specific surface area of 7 m²/g to 50 m²/g, and a hydrophobic group on a filler surface, and
wherein the second filler has a heat conductivity of 30 W/m·K or more.

2. The structure according to claim 1, wherein the structure has a film-like shape, and the first filler and the second filler each have a concentration gradient in a thickness direction of the film-like shape.

3. The structure according to claim 1, wherein the first filler has a particle size of 0.6 μm to 10 μm, and the second filler has a particle size of 10 μm to 100 μm.

4. The structure according to claim 1, wherein the structure includes the inorganic fillers in an amount of 66.3 volume % to 85.2 volume % with respect to a total volume of the structure.

5. An electronic component comprising the structure of claim 1.

6. An electronic device comprising the electronic component of claim 5.

7. An electronic component including a film comprising the structure of claim 1 layered thereon, wherein a concentration of the first filler becomes smaller toward the electronic device, and a concentration of second fillers becomes larger toward the heat generating device.
